(19) United States
(12) Patent Application Publication
(10) Pub. No.: US 2025/0207252 A1
(43) Pub. Date: Jun. 26, 2025

(54) REACTION CHAMBER, ATOMIC LAYER DEPOSITION APPARATUS AND A METHOD

(71) Applicant: BENEQ OY, Espoo (FI)

(72) Inventors: Pekka SOININEN, Espoo (FI); Markus BOSUND, Espoo (FI); Matti MALILA, Espoo (FI); Olli-Pekka SUHONEN, Espoo (FI)

(21) Appl. No.: 18/851,807

(22) PCT Filed: Mar. 29, 2023
(86) PCT No.: PCT/FI2023/050174

§ 371 Date: Sep. 27, 2024

(30) Foreign Application Priority Data
Mar. 30, 2022 (FI) 20225272

(51) Int. Cl. C23C 16/455; C23C 16/44; C23C 16/458; C23C 16/54

(52) U.S. Cl. CPC C23C 16/45544; C23C 16/4412; C23C 16/458; C23C 16/54

(57) ABSTRACT

A reaction chamber, apparatus and method for atomic layer deposition. The reaction chamber includes a gas inlet, a gas outlet arranged spaced apart from the gas inlet, and two or more substrate racks. Each of the substrate racks is arranged to support two or more separate substrates such that a substrate batch is formed. The two or more substrate racks are arranged inside the reaction space of the reaction chamber between the gas inlet and the gas outlet, and the two or more substrate racks are arranged in a row assembly between the gas inlet and the gas outlet.

### FIELD OF THE INVENTION

The present invention relates to a reaction chamber and more particularly to a reaction chamber for atomic layer deposition according to preamble of claim 1. The present invention also relates to an atomic layer deposition apparatus and more particularly to an atomic layer deposition apparatus according to preamble of claim 13. The present invention further relates to a method for loading substrates to a reaction chamber for atomic layer deposition and more particularly to a method according to preamble of claim 18.

### BACKGROUND OF THE INVENTION

In the prior art substrates, especially planar substrates such as semiconductor wafers, are processed as a batch in atomical layer deposition reactors. For processing the substrates need to be loaded into to a reaction chamber. In the loading the vacuum conditions of the atomic layer deposition apparatus need to be broken. Conventionally the reaction chamber is provided with substrate rack to each separate substrate is loaded separately for loading substrates inside the reaction chamber. Further, during unloading the vacuum conditions are again broken and each substrate is again unloaded separately from the reaction chamber.

One of the problems associated with the prior art is that that loading and unloading substrates separately into and from the reaction chamber is time consuming and the vacuum is broken for considerable time. When the vacuum is broken the processing is interrupted and overall efficiency of the apparatus is decreased. The overall efficiency of the apparatus may be slightly increased by increasing size of the substrate rack such that the batch size is increased. However, increasing the size of reaction chamber and the substrate rack compromises flow dynamics inside the reaction chamber and thus the quality of the process in compromised.

### BRIEF DESCRIPTION OF THE INVENTION

An object of the present invention is to provide a reaction chamber, atomic layer deposition apparatus and a method such that the prior art disadvantages may be solved or at least alleviated.

The objects of the invention are achieved by a reaction chamber which is characterized by what is stated in the independent claim 1. The objects of the invention are also achieved by an atomic layer deposition apparatus which is characterized by what is stated in the independent claim 13. The objects of the invention further achieved by a method for loading substrates into a reaction chamber which is characterized by what is stated in the independent claim 18.

The preferred embodiments of the invention are disclosed in the dependent claims.

The invention is based on the idea of providing a reaction chamber for atomic layer deposition, the reaction camber having a reaction space inside the reaction chamber and arranged to process multiple substrates concurrently in a batch process in the reaction space of the reaction chamber.

According to the present invention the reaction chamber comprises a gas inlet arranged to supply gases into the reaction space of the reaction chamber, a gas outlet arranged to discharge gases from the reaction space of the reaction chamber, the gas outlet being arranged spaced apart from the gas inlet, and two or more substrate racks. Each of the substrate racks is arranged to support two or more separate substrates such that a substrate batch is formed. The two or more substrate racks are arranged inside the reaction space of the reaction chamber between the gas inlet and the gas outlet, and the two or more substrate racks are arranged in a row assembly between the gas inlet and the gas outlet.

The row assembly means that the two or more substrate racks are arranged successively between the gas inlet and the gas outlet.

The row assembly of the substrate racks between the gas inlet and gas outlet enables processing great number of substrates and at the same time achieving uncompromised flow dynamics inside the reaction chamber. Cross-sectional area of the reaction chamber between the gas inlet and the gas outlet may be kept small and thus the flow dynamics remain uncompromised for a great number of processed substrates.

In some embodiments, the reaction chamber comprises a reaction chamber direction extending in the direction between the gas inlet and the gas outlet, and the two or more substrate racks are arranged in the row assembly in the reaction chamber direction between the gas inlet and the gas outlet.

Accordingly, the two or more substrate racks are arranged successively in the reaction chamber direction between the gas inlet and the gas outlet. Accordingly, the two or more substrate racks are arranged in the row assembly along the reaction chamber direction forming the flow direction of the gases from the gas inlet to the gas outlet. This provides efficient flow dynamics and enables subjecting all the substrates in the successive substrate racks to the gases.

In some embodiments, the two or more substrate racks are arranged in contact with each other and in the row between the gas inlet and the gas outlet. Thus, the two or more substrate racks are arranged against each other in the row assembly enabling compact assembly and use of space inside the reaction chamber.

In some embodiments, the substrate rack comprises an open front wall, an open back wall opposite the open front wall, a closed first side wall and a closed second side wall opposite the closed first side wall. The closed first and second side walls extend between then the open front wall and the open back wall such that a flow path through the substrate rack is formed between the open front wall and the open back wall. Accordingly, the open front and back walls and the closed first and second side walls generate a flow passage for the gases from the gas inlet to the gas outlet through the substrate rack such that the substrates are subjected to the gases.

In some other embodiments, the substrate rack comprises an open front wall, an open back wall opposite the open front wall, a closed first side wall, a closed second side wall opposite the closed first side wall and a closed top wall. The closed first and second side walls and the closed top wall extend between the open front wall and the open back wall such that a flow path through the substrate rack is formed between the open front wall and the open back wall. Accordingly, the open front and back walls, the closed first and second side walls and the closed top wall generate a flow tunnel for the gases from the gas inlet to the gas outlet through the substrate rack such that the substrates are subjected to the gases. Thus, the flow tunnel is formed inside the reaction chamber by the substrate rack and the two or more substrates are arranged inside the flow tunnel.

In some further embodiments, the substrate rack comprises an open front wall, an open back wall opposite the open front wall, a closed first side wall, a closed second side wall opposite the closed first side wall, a closed top wall and a closed bottom wall opposite the closed top wall, the closed first and second side walls and the closed top and bottom walls extending between then the open front wall and the open back wall such that a flow path through the substrate rack is formed between the open front wall and the open back wall. Accordingly, the open front and back walls, the closed first and second side walls and the closed top and bottom walls generate a flow channel for the gases from the gas inlet to the gas outlet through the substrate rack such that the substrates are subjected to the gases. Thus, the flow channel is formed inside the reaction chamber by the substrate rack and the two or more substrates are arranged inside the flow channel.

In some embodiments, the two or more substrate racks are arranged in the row assembly such that the open back wall of a substrate rack is towards the open front wall of a successive substrate rack in the row assembly such that a flow path through the two or more substrate racks is formed. Accordingly, the gases may flow through the successive substrate racks inside the reaction chamber and the substrates in the successive substrate racks are efficiently subjected to the gases.

In some other embodiments, the two or more substrate racks are arranged in the row assembly such that the open back wall of a substrate rack is against the open front wall of a successive substrate rack in the row assembly such that a continuous flow path through the two or more substrate racks is formed. The continuous flow path provides good flow dynamics and enables subjecting the substrates in the successive substrate racks efficiently to the gases.

In some embodiments, the open front wall of the substrate rack is arranged towards the gas inlet in the reaction space of the reaction chamber, and the open back wall of the substrate rack is arranged towards the gas outlet in the reaction space of the reaction chamber. Thus, gases may enter the flow path provided by the substrate racks directly form the gas inlet and the excessive gases are discharged directly from the flow path provided by the substrate racks to the gas outlet.

In some other embodiments, the open front wall of the substrate rack is arranged towards the gas inlet in the reaction space of the reaction chamber, and the open back wall of the substrate rack is arranged towards the gas outlet in the reaction space of the reaction chamber such the flow path through the substrate rack is arranged to extend in the reaction chamber direction of the reaction chamber. Accordingly, the flow path provided by the substrate racks is arranged to extend in the direction between the gas inlet and gas outlet for efficient gas flow inside the reaction chamber.

In some embodiments, the two or more substrate racks in the row are interconnected to each other, or successive substrate racks in the row are connected to each other directly with connection elements. Interconnecting or connecting the substrate racks to each other enables easy handling for loading and unloading of the substrate racks together into and from the reaction chamber. Further, interconnecting or connecting the substrate racks to each other enables providing the continuous flow path through the two or more substrate racks.

Accordingly the two or more substrate racks are arranged successively in the reaction chamber direction between the gas inlet and the gas outlet such that the flow path through the two or more substrate racks is provide to extend in the reaction chamber direction.

In some embodiments, the two or more substrate racks are supported on a common rack support. The rack support is arranged movable relative to the reaction chamber. Accordingly, the rack support may be moved for loading and unloading the two or more substrate racks into and form the reaction chamber. Further, during the movement the relative positions of the substrate racks do not change, and the two or more substrate racks do not move relative to each other.

In some other embodiments, the two or more substrate racks are supported on a common rack support. The rack support is arranged movable relative to the reaction chamber. The two or more substrate racks are interconnected to each other via the common rack support. Thus, the common substrate rack interconnects the two or more substrate racks together such that the two or more substrate racks may be moved together by moving the rack support.

In some further embodiments, the two or more substrate racks are supported on a common rack support. The rack support is arranged movable relative to the reaction chamber. Each of the two or more substrate racks are locked to the common rack support with locking elements. Therefore, the rack support is used for locking the two or more substrate racks relative to each other for moving them together and for forming the flow path through the two or more substrate racks.

In some embodiments, the substrate rack comprises substrate supports arranged to support two or more substrates between the closed first and second side walls. Accordingly, the substrates may be arranged to the flow path of the substrate rack.

In some other embodiments, the substrate rack comprises substrate supports arranged to support two or more substrates between the closed first and second side walls in a superposed arrangement such that a substrate stack is formed. Accordingly, two or more substrates may be supported in a superposed manner in the flow path of the substrate rack.

In some further embodiments, the substrate rack comprises substrate supports arranged to support two or more substrates between the closed first and second side walls and between the closed top wall and the closed bottom wall in a superposed arrangement such that a substrate stack is formed. Thus, two or more substrates may be arranged in superposed arrangement to the flow channel formed by the substrate rack.

In some embodiments, the reaction chamber comprises a support part arranged to support two or more substrate batches, each substrate batch comprising a stack of two or more separate substrates, and a cover part arranged to form a housing surrounding the two or more substrate batches supported on the support part. The support part and cover part are arranged to form the reaction chamber, the support part and the cover part being arranged movable relative to each other between the open position of the reaction chamber and a closed position of the reaction chamber, in which open position of the reaction chamber the support part and the cover part are spaced apart from each other and in the closed position of the reaction chamber the support part and the cover part are connected together for forming a closed reaction space inside the reaction chamber.

Accordingly, the support part is arranged to form a bottom wall of the reaction chamber. The cover part is arranged to form top wall and the side walls/side walls and end walls of the reaction chamber.

The reaction chamber may be opened and closed with one linear movement by providing movement of the support part and the cover part relative to each other.

In some embodiments, the reaction chamber comprises a first end, a second end opposite the first end, and a length between the first end and the second end. The reaction chamber further comprises a first side wall extending between the first end and the second end, a second side wall opposite the first side wall and extending between the first end and the second end, and a width between the first side wall and the second side wall. The reaction chamber has a first increasing width area from the first end towards the second end, and the reaction chamber has a second increasing width area from the second end towards the first end. The reaction chamber has a rack support area between the first increasing width area and the second increasing width area, and the two or more substrate racks are arranged inside the reaction space of the reaction chamber between the gas inlet and the gas outlet and to the rack support area.

In another embodiment, the cover part comprises a first end, a second end opposite the first end, and a length between the first end and the second end, the cover part further comprises a first side wall extending between the first end and the second end, a second side wall opposite the first side wall and extending between the first end and the second end, and a width between the first side wall and the second side wall. The cover part has a first increasing width area from the first end towards the second end, and the cover part has a second increasing width area from the second end towards the first end. The cover part has a rack support area between the first increasing width area and the second increasing width area, and the two or more substrate racks are arranged inside the reaction space of the reaction chamber between the gas inlet and the gas outlet and to the rack support area.

The increasing and decreasing width enables providing uniform gas flow and sufficient distance between the gas inlet from the substrates in the direction of the first and second end such that precursor gas molecules have adequate time and space to spread before meeting the substrates.

In some embodiments, the reaction chamber comprises bottom for supporting the two or more substrate racks, and the bottom is provided with heating element for heating the reaction space inside the reaction chamber.

In some other embodiments, the support part of the reaction chamber is provided with a heating element for heating the reaction space inside the reaction chamber.

Accordingly, the substrates and the reaction chamber may be efficiently heated, and heat may be provided to the reaction chamber via conduction via the bottom or the support part.

The above mentioned different embodiments of the reaction chamber may be combined in any feasible way without departing from the present invention.

The present invention is also based on the idea of providing an atomic layer deposition apparatus arranged to process multiple substrates concurrently in a batch process. The atomic layer deposition apparatus has a reaction chamber arranged inside a vacuum chamber. The atomic layer deposition apparatus further comprises a loading chamber connected to the vacuum chamber through a loading connection, and a loading arrangement arranged to move two or more substrate racks between the loading chamber and the reaction chamber inside the vacuum chamber through the loading connection. Each of the two or more substrate racks is arranged to support two or more substrates.

The reaction chamber comprises a support part forming a support for the two or more substrate racks, and a cover part forming a housing surrounding the two or more substrate racks arranged on the support part. The support part and the cover part together form the reaction chamber such that the cover part is movably arranged with respect to the support part between an open position of the reaction chamber and a closed position of the reaction chamber. In the open position of the reaction chamber the support part and the cover part are spaced apart from each other and in the closed position of the reaction chamber the support part and the cover part are connected together for forming a closed reaction chamber. The loading arrangement being arranged to move the two or more substrate racks together with a loading movement between the loading chamber and the reaction chamber inside the vacuum chamber through the loading connection in the open position of the reaction chamber.

The apparatus of the present invention enables loading and unloading great number of substrates into the reaction chamber with one loading movement and unloading movement. The two or more substrate racks enable arranging the great number of substrates without increasing size of the loading connection considerably.

In some embodiments, the two or more substrate racks are arranged in a row assembly, and that the loading arrangement is arranged to move the two or more substrate racks together in the row assembly with the loading movement between the loading chamber and the reaction chamber inside the vacuum chamber through the loading connection in the open position of the reaction chamber.

In some embodiments, the two or more substrate racks are arranged in contact or interconnected with each other in a row assembly such that a flow path through the two or more substrate racks is formed, and that the loading arrangement is arranged to move the two or more substrate racks together in the row assembly with the loading movement between the loading chamber and the reaction chamber inside the vacuum chamber through the loading connection in the open position of the reaction chamber.

The row assembly of the two or more enables minimizing the cross-sectional area of the two or more substrate racks during loading and unloading and thus also the size of the loading connection may be minimized. Arranging the two or more substrates in contact or interconnected with each other provides a compact rack assembly and the substrate racks are arranged in the assembly in which they are during processing in the reaction chamber.

In some embodiments, the two or more substrate racks are supported on a common rack support in the row assembly, and the loading arrangement is arranged to move the common rack support with the loading movement between the loading chamber and the reaction chamber inside the vacuum chamber through the loading connection in the open position of the reaction chamber. The common rack support provides a simple structure for connecting or interconnecting the two or more substrate racks together. Further, the common rack support enables loading and unloading the two or more substrate racks together as well as supporting the two or more substrate racks in the reaction chamber and in the loading chamber. Accordingly, the two or more substrate racks need not be moved relative to each other during loading, unloading and processing.

In some embodiments, the cover part is arranged movable in a first direction and the loading arrangement is arranged to move the two or more substrate racks in a second direction, which the second direction is transverse to the first direction. Thus, the whole loading and unloading may be carried out with two linear movements.

In some preferable embodiments, the second direction, meaning the loading direction, is parallel to the reaction chamber direction. Further, the flow path direction of the substrate racks is also preferably parallel to the second direction and to the reaction chamber direction. This provides efficient and simple loading together with improved flow dynamics in the reaction chamber.

In some embodiments, the atomic layer deposition apparatus further comprises a lifter connected to the reaction chamber and arranged to move the cover part between the open position and the closed position of the reaction chamber.

In some embodiments, the lifter is connected to the cover part of the reaction chamber and arranged to move the cover part in vertical direction relative to the support part of the reaction chamber, which the support part is arranged as stationary inside the vacuum chamber.

In some embodiments, the lifter is connected to the cover part of the reaction chamber and arranged to move the cover part in horizontal direction relative to the support part of the reaction chamber, which the support part is arranged as stationary inside the vacuum chamber.

In some embodiments, the lifter comprises a lifter motor arranged outside the vacuum chamber.

In some embodiments, the atomic layer deposition apparatus further comprises a thermal reflector arranged inside the vacuum chamber to surround at least part of the cover part of reaction chamber and to move together with the cover part.

In some embodiments, the atomic layer deposition apparatus further comprises a thermal reflector movably arranged inside the vacuum chamber such that, when the reaction chamber is in the closed position, the thermal reflector is arranged in a space between the loading connection and the reaction chamber, and when the reaction chamber is in the open position, the thermal reflector is moved away from the loading connection for providing an open path between the loading connection and the open reaction chamber.

In some embodiments, the thermal reflector is connected to the cover part of the reaction chamber such that the thermal reflector is movable together with the cover part.

In some alternative embodiments, the thermal reflector is connected to the lifter such that the thermal reflector is movable together with the lifter.

The atomic layer deposition apparatus further comprises a vacuum system arranged to provide vacuum conditions to the loading chamber and to the vacuum chamber.

In preferable embodiments, the reaction chamber of the atomic layer deposition apparatus is a reaction chamber as described above.

The present invention is further based on the idea of providing a method for loading substrates into a reaction chamber of an atomic layer deposition apparatus for processing the substrates according to the principles of atomic layer deposition method.

The method comprises the steps of:
arranging two or more substrate racks into a loading chamber, each of the two or more substrate racks comprise two or more substrates;
opening a loading connection between the loading chamber and a vacuum chamber;
moving the two or more substrate racks together from the loading chamber to the reaction chamber inside the vacuum chamber, the reaction chamber being in an open position in which a support part of the reaction chamber is spaced apart from a cover part of the reaction chamber; and
moving the reaction chamber from the open position to a closed position by providing a movement of the cover part with respect to the support part, in which closed position of the reaction chamber the support part and the cover part are connected together for forming a closed reaction space inside the reaction chamber.

Accordingly, the two or more substrate racks comprising two or more substrates is arranged into the loading chamber and the then the two or more substrate racks are moved together from the loading chamber to the reaction chamber inside the vacuum chamber with one loading movement. Therefore, great number of substrates may be loaded into the reaction chamber at once keeping the down time of the apparatus short.

In some embodiments, the step of moving the reaction chamber from the open position to the closed position further comprises moving the cover part in vertical direction with a lifter connected to the cover part, and connecting the cover part to the support part for closing the reaction chamber.

In some embodiments, the step of arranging the two or more substrate racks into a loading chamber comprises arranging the two or more in contact or interconnected with each other in a row assembly in the loading chamber such that a flow path through the two or more substrate racks is formed. Further, the step of moving the two or more substrate racks together from the loading chamber to the reaction chamber inside the vacuum chamber comprises moving the two or more substrate racks together in the row assembly from the loading chamber to the reaction chamber inside the vacuum chamber.

The row assembly of the two or more substrate racks enables utilizing compact sized loading connection between a loading chamber and the vacuum chamber. Further, the row assembly arranged in the loading chamber may be utilized in the reaction chamber during processing for efficient flow dynamics. Thus, the two or more substrate racks do not need to be moved relative to each other during or after loading into the reaction chamber.

In some other embodiments, the step of arranging the two or more substrate racks into a loading chamber comprises arranging the two or more substrate racks on a common rack support in a row assembly in the loading chamber such that a flow path through the two or more substrate racks is formed. Further, the step of moving the two or more substrate racks together from the loading chamber to the reaction chamber inside the vacuum chamber comprises moving the common rack support from the loading chamber to the reaction chamber inside the vacuum chamber, the two or more substrate racks being supported on the common rack support in the row assembly.

The common rack support provides a base for the two or more substrate racks during loading and unloading and during processing in the reaction chamber. Thus, the common rack support makes the handling of the two or more rack supports simple and efficient.

In a preferred embodiment, the method is carried out by an atomic layer deposition apparatus as disclosed above.

In another alternative embodiment, the method is carried out by an atomic layer deposition apparatus and with a reaction chamber as disclosed above.

An advantage of the invention is that the present invention enables utilizing standardized substrate stacks. Foe example, a standardized semiconductor wafer stack comprises 25 wafers. Thus, the present invention enables processing two or more standardized wafer stacks with the two or more substrates racks at once. This makes handling of the wafers efficient prior to atomic layer deposition processing and after it. Further, arranging the two or more substrate racks in a row assembly enables efficient loading and unloading through a compact sized loading connection in the direction of the row assembly. The row assembly of the two or more substrate racks also enables efficient flow dynamics inside the reaction chamber as the row assembly is arranged in a direction of the gas flow.

### BRIEF DESCRIPTION OF THE DRAWINGS

The invention is described in detail by means of specific embodiments with reference to the enclosed drawings, in which

FIG. 1 shows a schematic front view of a substrate rack;

FIG. 2 shows a schematic side view of the substrate rack of FIG. 1;

FIG. 3 shows a schematic side view of two substrate racks according one embodiment of the present invention;

FIG. 4 shows a schematic side view of two substrate racks according to another embodiment of the present invention;

FIG. 5 shows a schematic view of an atomic layer deposition apparatus according to one embodiment of the present invention;

FIG. 6 shows a schematic top view of a reaction chamber according to one embodiment of the present invention;

FIG. 7 shows a schematic side view of a reaction chamber of the FIG. 6;

FIG. 8 a schematic cross-sectional view of a reaction chamber of FIG. 7;

FIGS. 9 to 12 show schematically loading substrate racks into the reaction chamber of the atomic layer deposition apparatus according to the present invention; and

FIGS. 13 and 14 show schematically different embodiments of an atomic layer deposition apparatus according to the present invention.

### DETAILED DESCRIPTION OF THE INVENTION

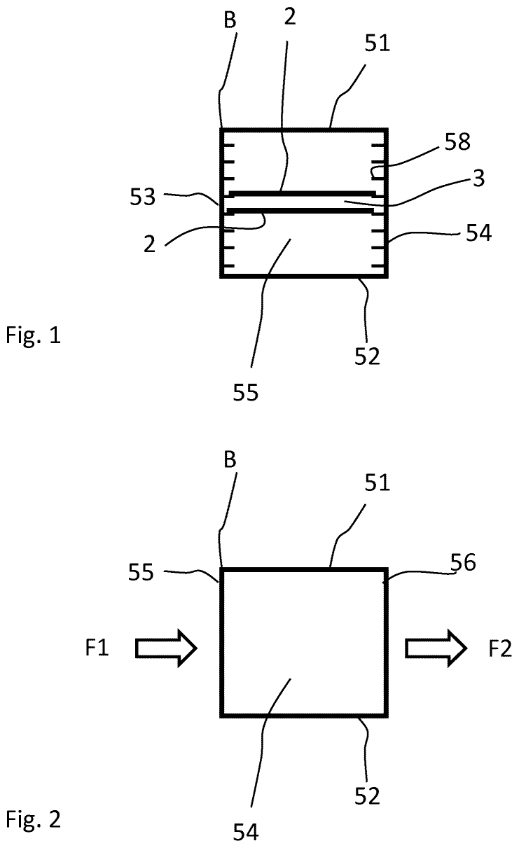

FIG. 1 shows a front view of a substrate rack B arranged to support two or more substrates 2. The substrates 2 planar substrates such as semiconductor wafers. FIG. 2 shows a side view of the substrate rack B of FIG. 1.

The substrate rack B comprises substrate supports 58 arranged to hold substrates 2 in the substrate rack B. The substrate supports 2 are arranged to support substrates 2 in superposed manner such that the substrates 2 are positioned on top of each other. Accordingly, a substrate stack is formed to the substrate rack B. The substrate supports 58 are arranged such that a gap 3 is provided between the superposed substrates 2 for providing gas flow between the superposed substrates 2.

In a preferred embodiment, the substrate rack B and the substrate supports 58 thereof are arranged to support 25 substrates 2 in superposed manner.

The substrate supports 58 arranged to support two or more substrates 2 between the closed first and second side walls 55, 56 in the superposed arrangement such that a substrate stack is formed.

The substrate rack B comprises an open front wall 55 and an open back wall 56 opposite the open front wall 55, as shown by FIGS. 1 and 2. The open front and back wall 55, 56 are arranged to enable gas flow via the open front and back wall 55, 56. The open front and back wall 55, 56 are also arranged to enable loading and unloading of substrates via the open front and back wall 55, 56.

The substrate rack B further comprises a closed first side wall 53 and a closed second side wall 54 opposite the closed first side wall 53. The closed first and second side walls 53, 54 extend between then the open front wall 55 and the open back wall 56 such that a flow path through the substrate rack B is formed from the open front wall 55 to the open back wall 56 and between the closed first and second side walls 53, 54.

According, a gas flow F1 is configured to enter into the substrate rack B via the open front wall 55 and a gas flow F2 is configured to exit from the substrate rack B via the open back wall 56. Thus, the gas flow is configured to flow though the substrate rack B via the open front wall 55 and open back wall 56 such that the substrates are subjected to the gas flow inside the substrate rack B.

The substrate rack B further comprises a closed top wall 51. The closed top wall 51 extends between the open front wall 55 and the open back wall 56 such that a flow path through the substrate rack B is formed from the open front wall 55 to the open back wall 56 and between the closed first and second side walls 53, 54 and the closed top wall 51. Accordingly, the closed first side wall 53, the closed second side walls 54 and the closed top wall 51 define the flow path as a flow tunnel from the open front wall 55 to the open back wall 56 through the substrate rack B.

In some embodiments, the closed top wall 51 may be omitted and the top wall may be open. In this case the uppermost substrate 2 may from a top wall for the substrate rack B.

The substrate rack B further comprises a closed bottom wall 52. The closed bottom wall 52 extends between the open front wall 55 and the open back wall 56 such that a flow path through the substrate rack B is formed from the open front wall 55 to the open back wall 56 and between the closed first and second side walls 53, 54 and the closed bottom wall 52. Accordingly, the closed first side wall 53, the closed second side walls 54 and the closed bottom wall 52 define the flow path as a flow tunnel from the open front wall 55 to the open back wall 56 through the substrate rack B.

Alternatively, the closed first side wall 53, the closed second side walls 54, the closed top wall 51 and the closed bottom wall 52 define the flow path as a flow channel from the open front wall 55 to the open back wall 56 through the substrate rack B.

The substrate supports 58 arranged to support two or more substrates 2 between the closed first and second side walls 55, 56 and between the closed top wall 51 and the closed bottom wall 52 in the superposed arrangement such that a substrate stack is formed.

In some embodiments, the closed bottom wall 52 may be omitted and the bottom wall may be open. In this case the lowermost substrate 2 may from a bottom wall for the substrate rack B.

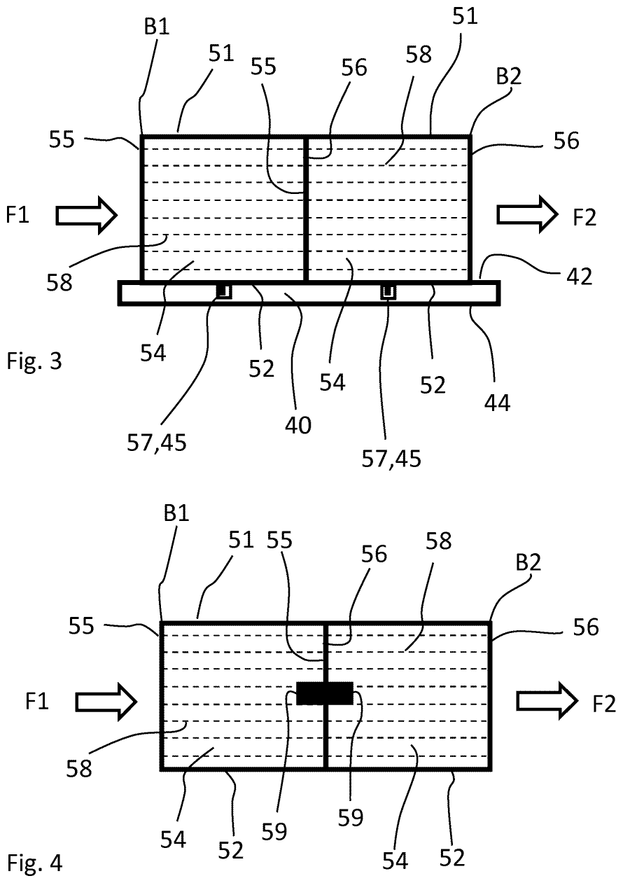

FIGS. 3 and 4 show two substrate racks B1 and B2 arranged together according to the present invention. It should be noted, that according to the present invention two or more substrate racks B1, B2 are arranged together. Thus, there may also be three or four substrate racks B1, B2 arranged together.

FIG. 3 shows one embodiment of arranging the substrate racks B1, B2 together. The substrate racks B1, B2 are arranged in the row assembly such that the open back wall 56 of a first substrate rack B1 is towards the open front wall 55 of a successive second substrate rack B2 in the row assembly such that a flow path through the first and second substrate racks B1, B2 is formed. According, the gas flow F1 is configured to enter into the first substrate rack B1 via the open front wall 55 of the first substrate rack B1 and a gas flow F2 is configured to exit from the second substrate rack B2 via the open back wall 56 of the second substrate rack B2. Thus, the gas flow is configured to flow though the first and second substrate racks B1, B2 via the open front wall 55 of the substrate rack B1 and open back wall 56 of the second substrate rack B2 such that the substrates in the first and second substrate racks B1, B2 are subjected to the gas flow.

As shown in FIG. 3, the first and second substrate racks B1, B2 are arranged in the row assembly such that the open back wall 56 of the first substrate rack B1 is against the open front wall 55 of the successive second substrate rack B2 in the row assembly such that a continuous flow path through the substrate racks B1, B2 is formed.

As shown in FIG. 3, the first and second substrate racks B1, B2 are supported on a common rack support 40. The rack support 40 is provided as separate element which is movable relative to a reaction chamber and atomic layer deposition apparatus.

The rack support 40 is provided as base plate having an upper support surface 42 and a bottom surface 44. The substrate racks B1, B2 are arranged to be supported on the upper surface 42 of the rack support 40. The substrate racks B1, B2 may be moved on the rack support 40 and together with the rack support 40 into a reaction chamber and from the reaction chamber. This makes handling of several substrate racks B1, B2 simple and efficient.

The substrate racks B1, B2 being interconnected to each other via the common rack support 40.

The substrate racks B1, B2 are locked or secured to the common rack support 40 with locking elements 45, 57. Thus, the substrate racks B1, B2 are arranged to be maintained in place in relation to each other and in relation to the rack support 40.

In the embodiment of FIG. 3, the locking elements 45, 57 comprises locking holes 45 provided to the rack support 40. The locking holes 45 are provided to the upper surface 42 of the rack support 40. The substrate racks B1, B2 are further provided with locking pins 57 extending downwards from the substrate racks B1, B2.

In some embodiments, the locking pins 57 are arranged to extend from the bottom wall 52 of the substrate racks B1, B2.

The substrate racks B1, B2 and arranged on the rack support 40 such that the locking pins 57 are placed into the locking holes 45. Thus, the locking holes 45 and the locking pins secure the substrate racks B1, B2 relative to each other and to the rack support 40.

In an alternative embodiment, the locking pins 57 are provided to the rack support 40 and on the upper surface 42 of the rack support 40. Thus, the locking holes 45 are provided to the substrate racks B1, B2.

It should be noted that the locking elements 57, 45 may also comprise other kind of locking elements, such as grooves, protrusions or the like.

The locking elements 57, 45 enable positioning the substrate racks B1, B2 on the common rack support 40 correctly.

FIG. 4 shows an alternative embodiment, in which the first and second substrate racks B1, B2 are directly connected or secured to each other with connection elements 59 in the row assembly.

In this embodiment, each of the substrate racks B1, B2 comprises connection elements 59 arranged to be connect with connection elements of a successive substrate rack B1, B2 in the row assembly.

In the embodiment of FIG. 4, the common rack support 40 may be omitted. However, the common rack support 40 may also be utilized in the embodiment of FIG. 4. However, the locking elements 57, 45 may be omitted.

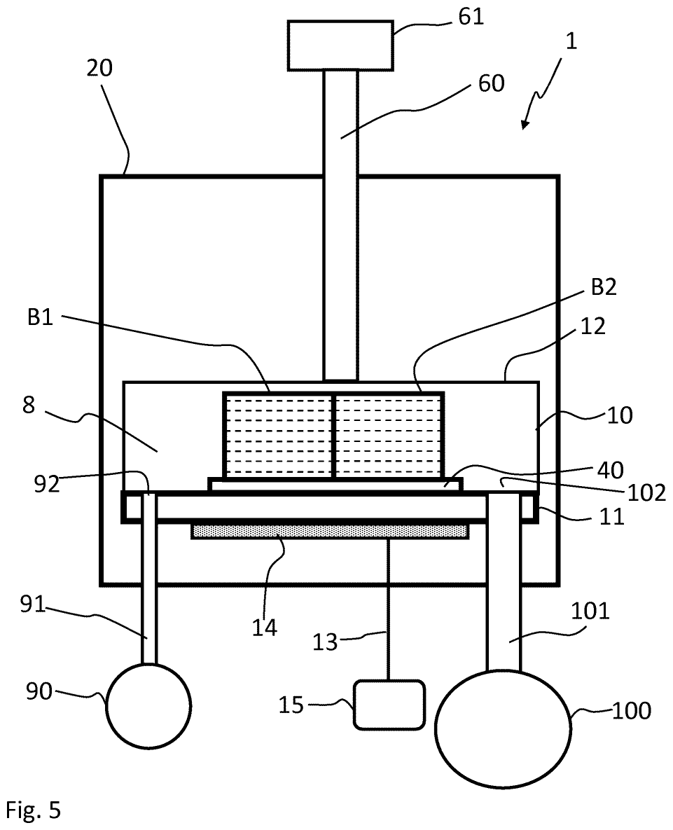

FIG. 5 shows an atomic layer deposition apparatus 1 having a reaction chamber 10 arranged inside a vacuum chamber 20. The reaction chamber 10 is arranged to process substrates according to the principles of atomic layer deposition method in a batch process in which the substrate racks B1, B2 are provided inside the reaction chamber 10 for simultaneously processing the substrates 2 arranged in connection with the substrate racks B1, B2. The reaction chamber 10 defines a reaction space 8 inside the reaction chamber 10.

The atomic layer deposition apparatus 1 comprises the reaction chamber 10 comprising a support part 11 forming a support for the substrate batch and substrate racks B1, B2 inside the reaction chamber 10. The reaction chamber 10 also comprises a cover part 12 forming a housing surrounding the substrate racks B1, B2 placed on the support part 11.

In the embodiment of FIG. 5, the support part 11 is arranged to form a bottom of the reaction chamber 10 and the cover part 12 forming the reactor side walls and a reactor roof or top wall. The support part 11 and the cover part 12 together form the reaction chamber 10 such that the cover part 12 is movably arranged with respect to the bottom part 11.

The atomic layer deposition apparatus further comprises a gas supply conduit 91 connected to the support part 11 of the reaction chamber 10 such that the gases are supplied from a gas source 90 through the support part 11 into the reaction chamber 10 via a gas inlet 92. A discharge conduit 101 is also connected to the support part 11 of the reaction chamber 10 with a gas outlet 102 such that the gases are discharged from the reaction chamber 10 through the support part 11 to a discharge system 100 via the discharge conduit 101.

The atomic layer deposition apparatus comprises a lifter 60 connected to the cover part 12. The lifter comprises a lifter motor 61 arranged outside the vacuum chamber 20. The lifter 60 is arranged to move the cover part 12 in relation to support part 11 inside the vacuum chamber 20 for opening and closing the reaction chamber 10.

In an alternative embodiment, the lifter 60 is connected to the support part 11 and arranged to move the support part 11 in relation to the cover part 12 for opening and closing the reaction chamber 10.

The support part 11 and cover part 12 are arranged movable relative to each other between the open position of the reaction chamber 10 and a closed position of the reaction chamber 10 with the lifter 60. In the open position of the reaction chamber 10 the support part 11 and the cover part 12 are spaced apart from each other. In the closed position of the reaction chamber 10 the support part 11 and the cover part 12 are connected together for forming a closed reaction space 8 inside the reaction chamber 10, as shown in FIG. 5.

The support part 11 is provided with a heating element 14 for heating the reaction space 8 inside the reaction chamber 10.

The heating element 14 is an electrical heating element connected to a power source 15 with a power line 13. The power source 15 is arranged outside the vacuum chamber 20. The power source 15 may be for example any kind of electrical connection.

As shown in FIG. 5, the heating element 14 is arranged to heat the support part 11 which is in contact with the common rack support 40 or alternatively directly with the substrate racks B1, B2. Thus, the heating of the substrates 2 in the substrate racks B1, B2 is carried out efficiently.

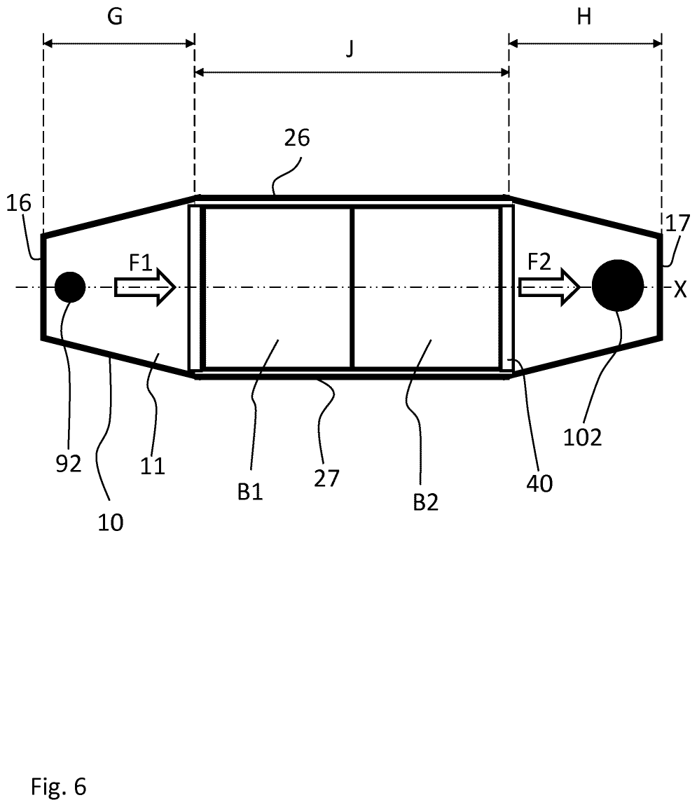

The substrate racks B1, B2 are arranged in the row assembly inside the reaction chamber 10. The arrangement of the substrate racks B1, B2 inside the reaction chamber are shown in more detail in FIGS. 6, 7 and 8.

FIG. 6 shows a schematic top view of the reaction chamber 10 with the substrate racks B1, B2 supported on the support part 11.

The reaction chamber 10 comprises a first end 16, a second end 17 opposite the first end 16, and a length between the first end 16 and the second end 17. The reaction chamber 10 further comprises a first side wall 26 extending between the first end 16 and the second end 17, a second side wall 27 opposite the first side wall 26 and extending between the first end 16 and the second end 17, and a width between the first side wall 26 and the second side wall 27.

In the embodiment of FIGS. 6-8 the end walls 16, 17 and the side walls 26, 27 are provided to the cover part 12.

The reaction chamber 10 or the cover part 12 has a first increasing width area G from the first end 16 towards the second end 17. In the first increasing width area G the distance between the first and second side walls 26, 27 increases in the direction towards the second end 17. The gas inlet 92 is arranged to the first increasing width area G.

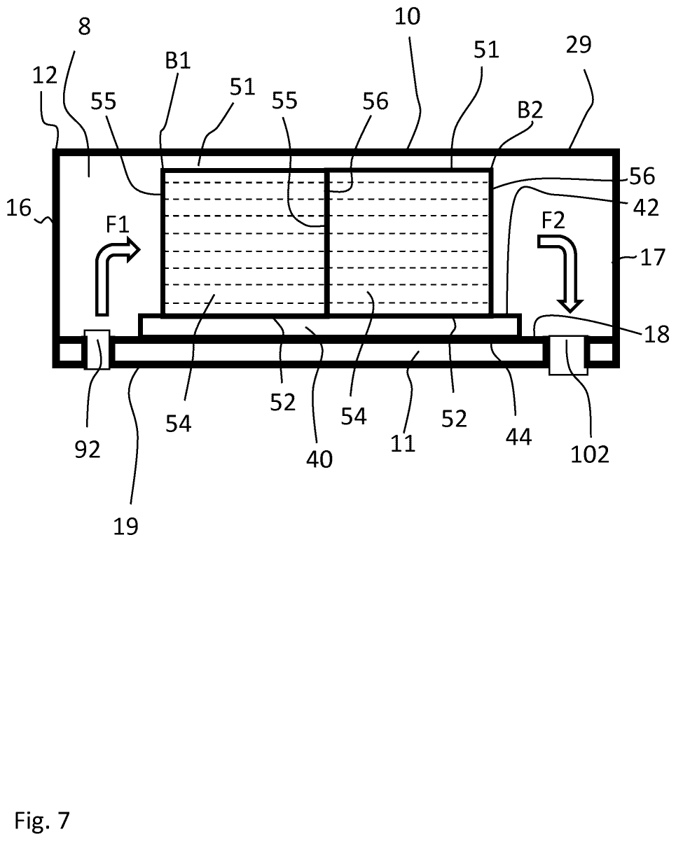

The gas inlet 92 is provided to the support part 11 and the gas supply conduit 91 extends through the support part 11 from the lower surface 19 to the upper surface 18 of the support part 11, as show in FIG. 7.

The reaction chamber 10 or the cover part 12 also has a second increasing width area H from the second end 17 towards the first end 16. In the second increasing width area H the distance between the first and second side walls 26, 27 increases in the direction towards the first end 16. The gas outlet 102 is arranged to the second increasing width area H.

The gas outlet 102 is provided to the support part 11 and the discharge conduit 101 extends through the support part 11 from the lower surface 19 to the upper surface 18 of the support part 11, as show in FIG. 7.

The reaction chamber 10 or the cover part 12 further has a rack support area J between the first increasing width area G and the second increasing width area H.

In some embodiments, the width along the rack support area J is substantially constant.

In some other embodiments, the width along the rack support area J is varying.

The substrate racks B1, B2 are arranged inside the reaction space 8 of the reaction chamber 10 between the gas inlet 92 and the gas outlet 102 and I the row assembly.

Further, the substrate racks B1, B2 are arranged to the rack support area J.

The reaction chamber 10 comprises a reaction chamber direction X extending in the direction between the gas inlet 92 and the gas outlet 102, as shown in FIG. 6. The two or more substrate racks B1, B2 are arranged in the row assembly in the reaction chamber direction X between the gas inlet 92 and the gas outlet 102. Accordingly, the row of substrate racks B1, B2 extends in the reaction chamber direction X.

As shown in FIG. 7, the open front wall 55 of the substrate racks B1, B2 is arranged towards the gas inlet 92 in the reaction space 8 of the reaction chamber 10. Thus, the open front wall 55 is towards the first end 16.

Similarly, the open back wall 56 of the substrate racks B1, B2 is arranged towards the gas outlet 102 in the reaction space 8 of the reaction chamber 10. Thus, the open back wall 55 is towards the second end 17.

The first and second substrate racks B1, B2 are arranged in the row assembly and in contact with each other such the continuous flow path through the first and second substrate racks B1, B2 is formed and arranged to extend in the reaction chamber direction X of the reaction chamber 10.

The first and second substrate racks B1, B2 are arranged to the row assembly as disclosed in connection with FIGS. 1 to 4.

As shown in FIG. 7, the first and second substrate racks B1, B2 are arranged in the row assembly such that the open back wall 56 of the first substrate rack B1 is against the open front wall 55 of the successive second substrate rack B2 in the row assembly such that the continuous flow path through the substrate racks B1, B2 is formed. The open front wall 55 of the first substrate rack B1 is open towards the gas inlet 92. The open back wall 56 of the second substrate rack B2 is open towards the gas outlet 102.

Accordingly, the gas flow F1 supplied from the gas inlet 92 enters the continuous flow path via the open front wall 92 of first substrate rack B1, or first in the row assembly, and flows through the first and second substrate racks B1, B2. The gas flow F2 exits the continuous flow path via the open back wall of the second substrate rack B2, or last in the row assembly, and is discharged from the reaction chamber 10 via the gas outlet 102.

The first and second substrate racks B1, B2 are supported on the rack support 40, which is movable in relation to the reaction chamber 10. The rack support 40 is arranged on the support part 11 and on the upper surface of the support part 11.

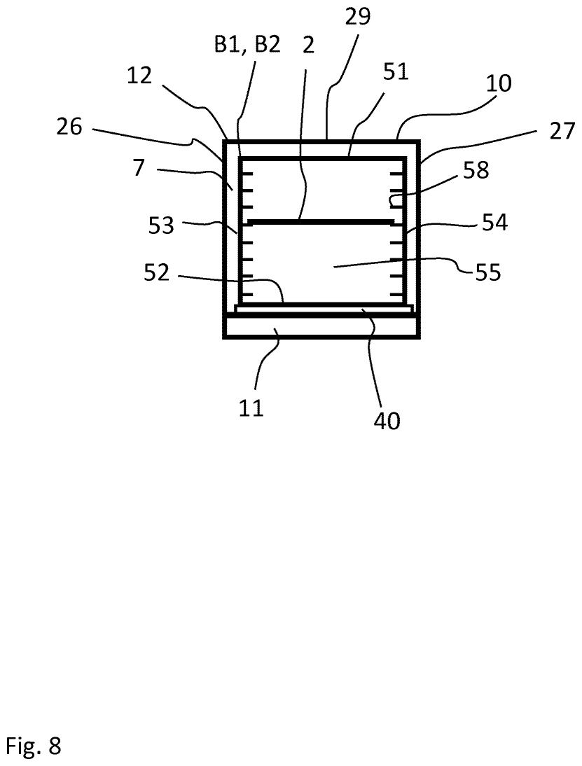

FIG. 8 shows a schematic cross-sectional end view of the reaction chamber 10 and the substrate racks B1, B2 between the first and second end 16, 17. There is small gap 7 between the closed walls 51, 53, 54 of the substrate racks B1, B2 and the walls 29, 26, 27 of the reaction chamber 10 or the cover part 12.

Preferably the gap 7 is uniform between the top wall 51 of the substrate racks B1, B2 and the top wall 29 of the reaction chamber 10, the closed first and second side walls 16, 17 of the substrate racks B1, B2 and the first and second side walls 26,27 of the reaction chamber 10. Therefore, a uniformly distributed gas flow is achieved inside the reaction chamber 10 between the gas inlet 92 and the gas outlet 102.

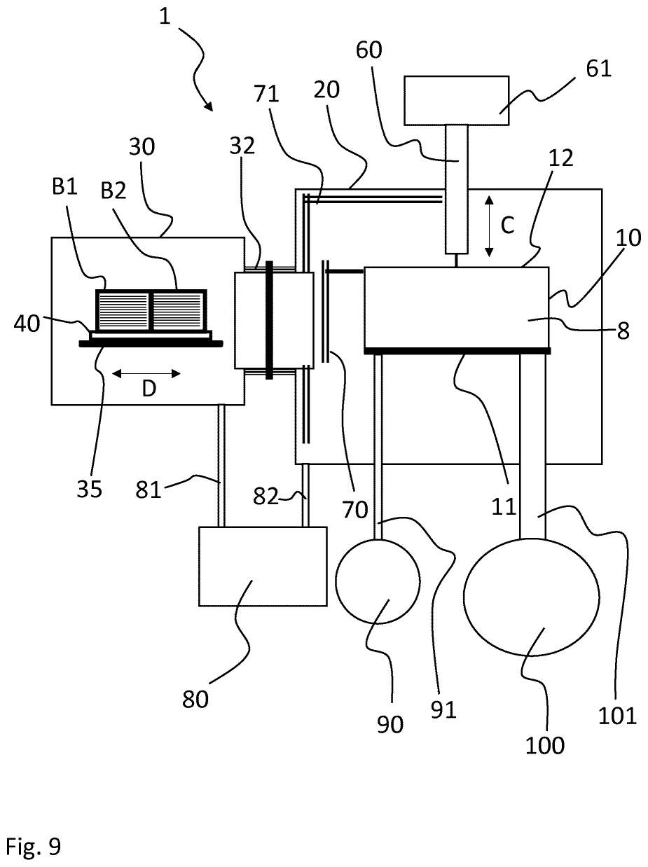

FIG. 9 shows the atomic layer deposition apparatus 1 having the reaction chamber 10 arranged inside a vacuum chamber 20. The reaction chamber 10 is arranged to process substrates according to the principles of atomic layer deposition method in a batch process in which a substrate racks B1, B2 are provided inside the reaction chamber 10 for simultaneously processing the substrates arranged in connection with the substrate racks B1, B2. The atomic layer deposition apparatus 1 further comprises a loading chamber 30 connected to the vacuum chamber 20 through a loading connection 32. The loading connection 32 is arranged to provide a loading path for the substrate racks B1, B2 provided in the loading chamber 30 to be moved from the loading chamber 30 to the reaction chamber 10 inside the vacuum chamber 20 and back from the reaction chamber 10 to the loading chamber 30.

The loading connection 32 may comprises or is a gate valve. In some embodiment the gate valve is a pendulum gate valve, but may also be any other suitable gate valve.

A loading arrangement 35 is arranged to move the substrate racks B1, B2 between the loading chamber 30 and the reaction chamber 10 inside the vacuum chamber 20 through the loading connection 32 along the loading path. The substrate racks B1, B2 are arranged on the rack support 40 in the row assembly. The rack support 40 is arranged to be moved with the loading arrangement 35 for loading and unloading. Thus, the substrate racks B1, B2 do not need to be moved separately, but they are moved together on the rack support 40.

The atomic layer deposition apparatus 1 comprises the reaction chamber 10 comprising the support part 11 forming the support for the rack support 40 and the substrate racks B1, B2 and the cover part 12 forming a housing surrounding the substrate batch placed on the support part. The support part 11 forming and in this embodiment of the invention also the bottom of the reaction chamber 10 and the cover part 12 forming the reactor side walls and a reactor roof.

The support part 11 and the cover part 12 together form the reaction chamber 10 such that the cover part 12 is movably arranged with respect to the bottom part 11 between the open position of the reaction chamber 10 and the closed position of the reaction chamber 10.

The FIG. 9 shows the reaction chamber 10 in the closed position such that the cover part 12 and the support part 11 are connected together for forming the closed reaction space 8 inside the reaction chamber 10. The loading connection 32 arranged to connect the loading chamber 30 and the vacuum chamber 20 having the reaction chamber 10 inside is also in a closed position, separating the loading chamber 30 from the vacuum chamber 20. The substrate racks B1, B2 are loaded in the loading chamber 30 on the loading arrangement 35 into the row assembly on the rack support 40.

The apparatus 1 further comprises a vacuum system 80 connected with a first vacuum connection 81 to the loading chamber 30 and with a second vacuum connection 82 to the vacuum chamber 20. The vacuum system 80 comprises a vacuum pump.

Alternatively, the vacuum system 80 comprises a first vacuum pump connected to the loading chamber 30 and a second vacuum pump connected to the vacuum chamber 20.

The vacuum system 80 is arranged to provide vacuum conditions to the loading chamber 30.

The vacuum system 80 is also arranged to provide vacuum conditions to the vacuum chamber 20.

The FIG. 9 also shows additional thermal reflectors 71 provided on the inner surfaces of the vacuum chamber 20. However, these additional thermal reflectors 71 are not mandatory but they can be arranged to protect for example surrounding areas of the loading connection 32 or the surrounding areas of the lifter 60.

The support part 11 is throughout in this application the part on which the substrate racks B1, B2 are placed for processing the substrates in the reaction chamber 10 and which stays stationary inside the vacuum chamber 20. The arrows C and D present the movement directions of the cover part 12 and of the loading arrangement 35, such that the arrow C represents the reciprocating movement in a first direction and the arrow D represents the reciprocating movement in a second direction which is transverse to the first direction.

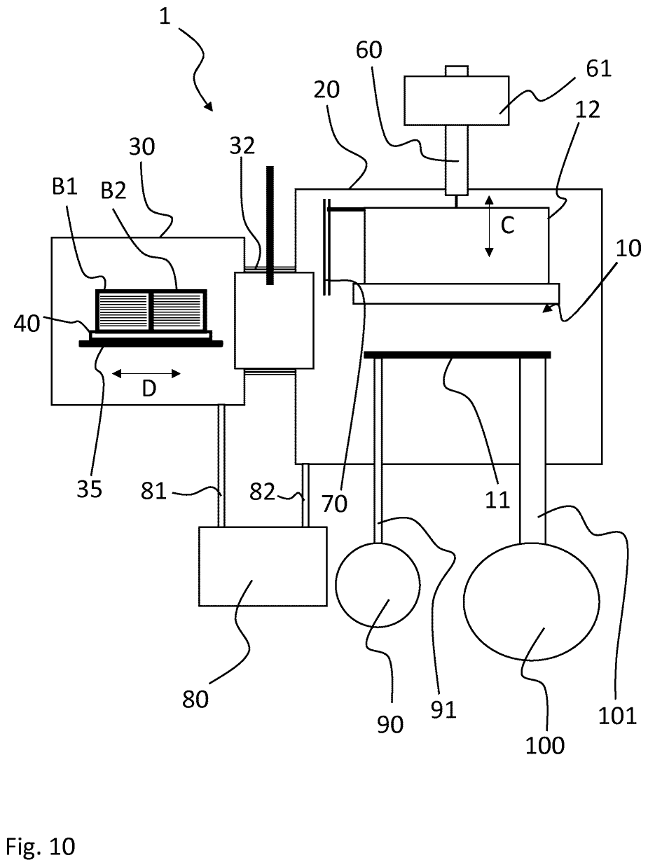

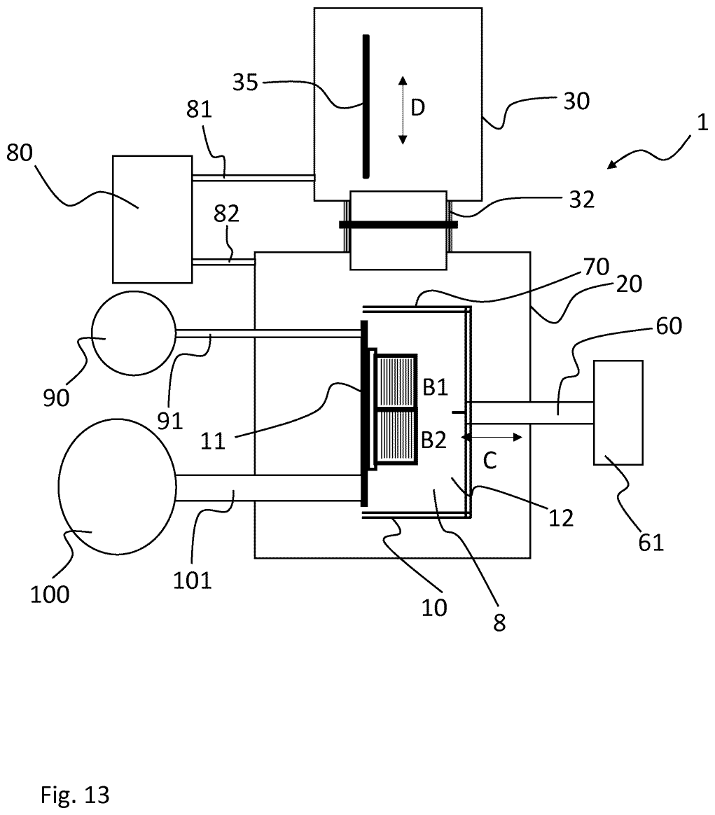

The FIG. 10 shows that the loading connection 32 connecting the loading chamber 30 and the vacuum chamber 20 is open which means that the vacuum system has provided vacuum conditions to the loading chamber 30 and to the vacuum chamber 20 such that the substrates racks B1, B2 can be moved from the loading chamber 30 to reaction chamber 10 inside the vacuum chamber 20 without breaking the vacuum. The cover part 12 of the reaction chamber 10 has been moved with the lifter 60 having the lifter motor 61 outside the vacuum chamber 20 such that the lifter 60 extends from outside of the vacuum chamber to inside of the vacuum chamber 20 and is connected to the cover part 12 of the reaction chamber 10. In the open position of the reaction chamber 10 the cover part 12 is moved to the upper part of the vacuum chamber 20 with the lifter 60 and the cover part 12 is spaced apart from the support part 11 which remains in its position. The support part 11 is arranged at the same level with the loading arrangement 35 such that the loading path between the loading chamber 30 and the reaction chamber 10 is horizontal. The atomic layer deposition apparatus 1 further comprises a thermal reflector 70 arranged to prevent heat coming from the reaction chamber 10 to reflect to the loading connection 32. In this embodiment of the invention the thermal reflector 70 is arranged in connection with the cover part 12 of the reaction chamber 10 and moved away from the space between the reaction chamber 10 and the loading connection 32 as the cover part 12 is moved to the upper part of the vacuum chamber 20 thereby providing an open loading path for the substrate racks B1, B2. FIG. 13 shows another embodiment in connection with the thermal reflectors.

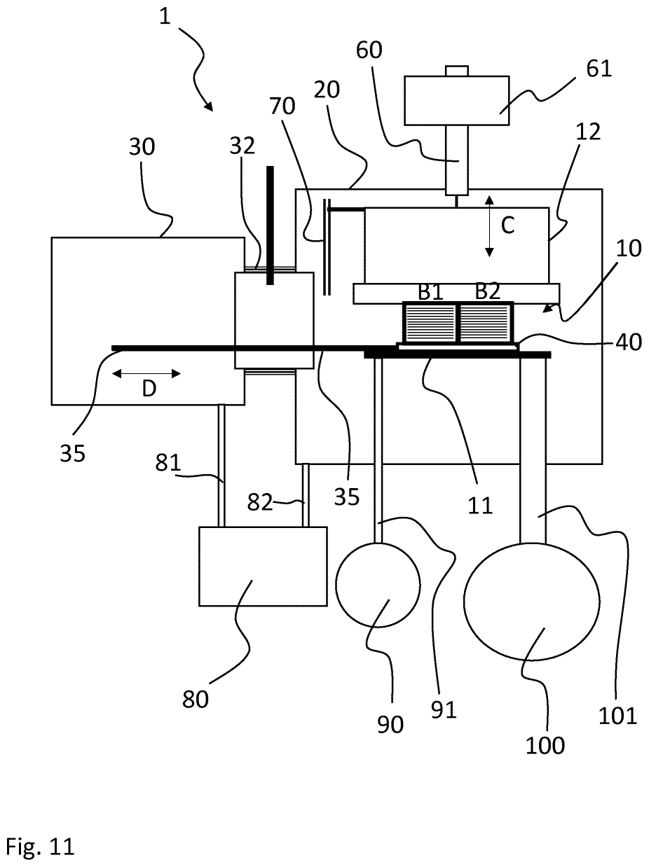

The FIG. 11 shows a state of the atomic layer deposition apparatus 1 in which the substrate racks B1, B2 are moved from the loading chamber 30 to the reaction chamber 10 inside the vacuum chamber 20 in the second direction D. The reaction chamber 10 is still open and the loading arrangement 35 extends from the loading chamber 30 to the reaction chamber 10. The vacuum conditions are provided in both the loading chamber 30 and the reaction chamber 10 open to the vacuum chamber 20.

The second direction D, meaning the loading direction, is parallel to the reaction chamber direction X. Further, the flow path direction of the substrate racks B1, B2 is also preferably parallel to the second direction D during the loading with the loading arrangement 35 and in the reaction chamber. Thus, flow path direction of the substrate racks B1, B2 is also parallel to the second direction D.

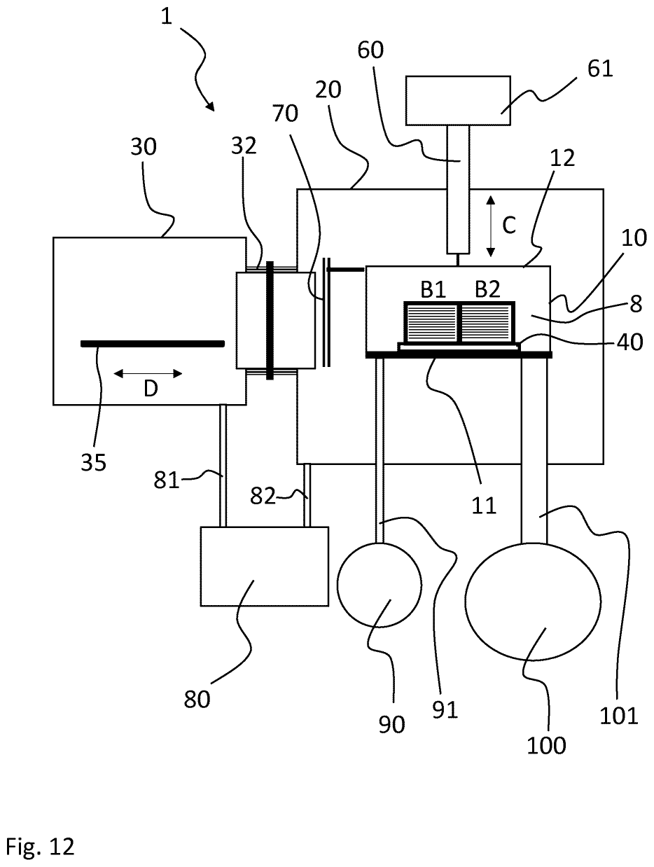

The FIG. 12 shows a state of the atomic layer deposition apparatus 1 in an operation mode in which the cover part 12 of the reaction chamber 10 has been brought and arranged into contact with the support part 11 of the reaction chamber 10 by operating the lifter motor 61 for moving the cover part 12 by the lifter 60 so that the cover part 12 is engaged with the support part 11. The cover part 12 has moved in the first direction C. The thermal reflector 70 is also brought in its place in the space between the reaction chamber 10 and the loading connection 32 such that the thermal reflector 70 prevents heat from the reaction chamber 10 to transfer to the loading connection 32. The loading connection 32 is closed and the loading chamber 30 has been separated from the vacuum chamber 20 through the closed loading connection 32. The substrates provided in the substrate racks B1, B2 are processed in the reaction chamber 10 according to the principles of atomic layer deposition method.

The FIG. 13 shows the atomic layer deposition apparatus 1 according to the invention, in which the loading chamber 30 is arranged above the vacuum chamber 20 such that the loading movement of the substrate racks B1, B2 is in vertical direction, i.e. the second direction D is in this embodiment vertical. Although the FIG. 13 shows that the loading chamber 30 is above the vacuum chamber 20, the loading chamber 30 can alternatively be provided below the vacuum chamber 20. The movement direction of the cover part 12, i.e. the first direction C is in this embodiment horizontal. The support part 11 comprises a connection arrangement for the substrate racks B1, B2 or the rack support 40 for connecting to the support part 11 provided in vertical direction.

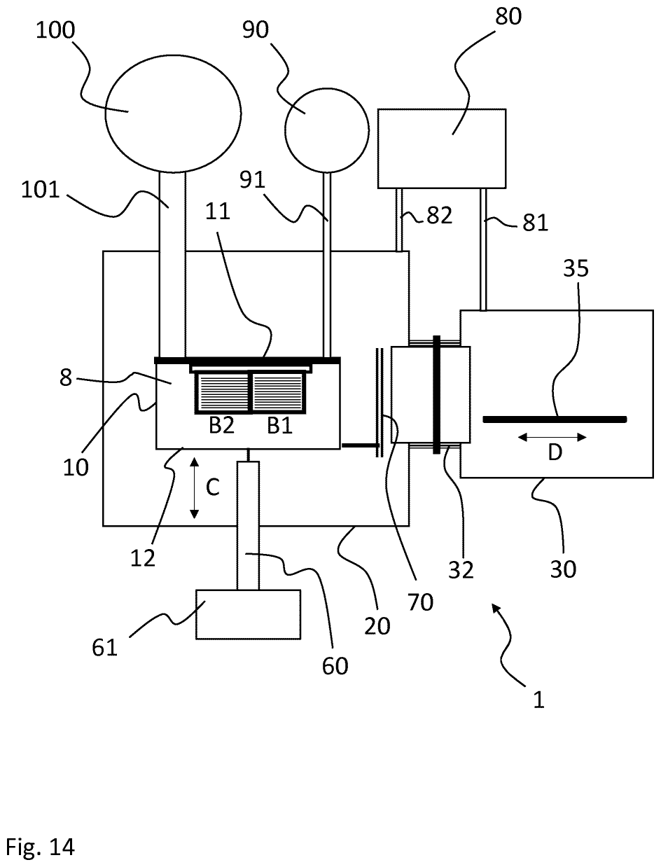

FIG. 13 shows also another way to provide the thermal reflector 70 in connection with the reaction chamber 10 for preventing heat to enter the loading chamber 30. The thermal reflector 70 is arranged to cover at least part of the reaction chamber 10 and in this version shown in FIG. 14 the thermal reflector 70 surrounds the cover part 12.

The FIG. 14 shows an alternative way to arrange the reaction chamber 20 inside the vacuum chamber 20. Although the loading chamber 30 is arranged on the opposite site of the vacuum chamber 20 than presented in the FIG. 9, it does not limit this embodiment in any way. The support part 11 is arranged as stationary inside the vacuum chamber 20 so that the cover portion 12 moves from below toward the support part 11 and the substrate batch is suspended therein. The first direction C and the second direction D are however the same as in the FIG. 9. The gas supply and discharge are still provided through the support part 11 to and from the reaction chamber 10 similarly as in connection with all the other embodiments shown in FIGS. 9-13.

In the context of the present invention there may be two, three, four or more substrate racks B, B1, B2 loaded together simultaneously from the loading chamber 30 to the reaction chamber 10, and also unloaded from the reaction chamber to the loading chamber 30.

Further, in this application the substrates racks B, B1, B2 are arranged in the loading chamber to the row assembly.

The row assembly has preferably a row direction, row is formed in the row direction, which is parallel to the second direction D. Accordingly, the loading and unloading of the substrate racks B1, B2 is carried out in the row direction with the loading arrangement 35. Thus, size of loading connection, or loading opening thereof, may be minimized.

In FIGS. 9 to 14 the substrate racks B1, B2 are arranged to the row assembly in the loading chamber 30 and on the rack support 40. The loading arrangement 35 is arranged to connect with the rack support 40 for moving the in the second direction D. Thus, during loading and unloading and well as during processing the substrate racks B1, B2 need not to be moved separately. Therefore, the substrate racks B1, B2 remain stationary in relation to each other enabling exact mutual positioning of the substrate racks B1, B2.

The invention has been described above with reference to the examples shown in the figures. However, the invention is in no way restricted to the above examples but may vary within the scope of the claims.

1.-21. (canceled)

22. A reaction chamber for atomic layer deposition, the reaction camber having a reaction space inside the reaction chamber and arranged to process multiple substrates concurrently in a batch process in the reaction space of the reaction chamber, wherein the reaction chamber comprises:
a gas inlet arranged to supply gases into the reaction space of the reaction chamber;
a gas outlet arranged to discharge gases from the reaction space of the reaction chamber, the gas outlet being arranged spaced apart from the gas inlet; and
two or more substrate racks, each of the substrate racks being arranged to support two or more separate substrates such that a substrate batch is formed,
the two or more substrate racks are arranged inside the reaction space of the reaction chamber between the gas inlet and the gas outlet, and
the two or more substrate racks are arranged in a row assembly between the gas inlet and the gas outlet.

23. The reaction chamber according to claim 22, wherein the reaction chamber comprises a reaction chamber direction extending in the direction between the gas inlet and the gas outlet, and that the two or more substrate racks are arranged in the row assembly in the reaction chamber direction between the gas inlet and the gas outlet.

24. The reaction chamber according to claim 22, wherein the two or more substrate racks are arranged in contact with each other and in the row between the gas inlet and the gas outlet.

25. The reaction chamber according to claim 22, wherein the substrate rack comprises:
an open front wall, an open back wall opposite the open front wall, a closed first side wall and a closed second side wall opposite the closed first side wall, the closed first and second side walls extending between then the open front wall and the open back wall such that a flow path through the substrate rack is formed between the open front wall and the open back wall; or
an open front wall, an open back wall opposite the open front wall, a closed first side wall, a closed second side wall opposite the closed first side wall and a closed top wall, the closed first and second side walls and the closed top wall extending between the open front wall and the open back wall such that a flow path through the substrate rack is formed between the open front wall and the open back wall; or
an open front wall, an open back wall opposite the open front wall, a closed first side wall, a closed second side wall opposite the closed first side wall, a closed top wall and a closed bottom wall opposite the closed top wall, the closed first and second side walls and the closed top and bottom walls extending between then the open front wall and the open back wall such that a flow path through the substrate rack is formed between the open front wall and the open back wall.

26. The reaction chamber according to claim 25, wherein:
the two or more substrate racks are arranged in the row assembly such that the open back wall of a substrate rack is towards the open front wall of a successive substrate rack in the row assembly such that a flow path through the two or more substrate racks is formed; or
the two or more substrate racks are arranged in the row assembly such that the open back wall of a substrate rack is against the open front wall of a successive substrate rack in the row assembly such that a continuous flow path through the two or more substrate racks is formed.

27. The reaction chamber according to claim 25, wherein:
the open front wall of the substrate rack is arranged towards the gas inlet in the reaction space of the reaction chamber, and the open back wall of the substrate rack is arranged towards the gas outlet in the reaction space of the reaction chamber; or
the open front wall of the substrate rack is arranged towards the gas inlet in the reaction space of the reaction chamber, and the open back wall of the substrate rack is arranged towards the gas outlet in the reaction space of the reaction chamber such the flow path through the substrate rack is arranged to extend in the reaction chamber direction of the reaction chamber.

28. The reaction chamber according to claim 22, wherein:
the two or more substrate racks in the row are interconnected to each other; or
successive substrate racks in the row are connected to each other directly with connection elements.

29. The reaction chamber according to claim 22, wherein:
the two or more substrate racks are supported on a common rack support, the rack support being arranged movable relative to the reaction chamber; or
the two or more substrate racks are supported on a common rack support, the rack support being arranged movable relative to the reaction chamber, the two or more substrate racks being interconnected to each other via the common rack support; or
the two or more substrate racks are supported on a common rack support, the rack support being arranged movable relative to the reaction chamber, each of the two or more substrate racks being locked to the common rack support with locking elements.

30. The reaction chamber according to claim 22, wherein:
the substrate rack comprises substrate supports arranged to support two or more substrates between the closed first and second side walls; or
the substrate rack comprises substrate supports arranged to support two or more substrates between the closed first and second side walls in a superposed arrangement such that a substrate stack is formed; or
the substrate rack comprises substrate supports arranged to support two or more substrates between the closed first and second side walls and between the closed top wall and the closed bottom wall in a superposed arrangement such that a substrate stack is formed.

31. The reaction chamber according to claim 22, wherein the reaction chamber comprises:
a support part arranged to support two or more substrate batches, each substrate batch comprising a stack of two or more separate substrates, and
a cover part arranged to form a housing surrounding the two or more substrate batches supported on the support part,
the support part and cover part are arranged to form the reaction chamber, the support part and the cover part being arranged movable relative to each other between the open position of the reaction chamber and a closed position of the reaction chamber, in which open position of the reaction chamber the support part and the cover part are spaced apart from each other and in the closed position of the reaction chamber the support part and the cover part are connected together for forming a closed reaction space inside the reaction chamber.

32. The reaction chamber according to claim 22, wherein:
the reaction chamber comprises a first end, a second end opposite the first end, and a length between the first end and the second end, the reaction chamber further comprises a first side wall extending between the first end and the second end, a second side wall opposite the first side wall and extending between the first end and the second end, and a width between the first side wall and the second side wall,
the reaction chamber having a first increasing width area from the first end towards the second end,
the reaction chamber having a second increasing width area from the second end towards the first end,
the reaction chamber having a rack support area between the first increasing width area and the second increasing width area, and
the two or more substrate racks are arranged inside the reaction space of the reaction chamber between the gas inlet and the gas outlet and to the rack support area; or
the cover part comprises a first end, a second end opposite the first end, and a length between the first end and the second end, the cover part further comprises a first side wall extending between the first end and the second end, a second side wall opposite the first side wall and extending between the first end and the second end, and a width between the first side wall and the second side wall,
the cover part having a first increasing width area from the first end towards the second end,
the cover part having a second increasing width area from the second end towards the first end,
the cover part having a rack support area between the first increasing width area and the second increasing width area, and
the two or more substrate racks are arranged inside the reaction space of the reaction chamber between the gas inlet and the gas outlet and to the rack support area.

33. An atomic layer deposition apparatus arranged to process multiple substrates concurrently in a batch process, the atomic layer deposition apparatus having a reaction chamber arranged inside a vacuum chamber, wherein the atomic layer deposition apparatus further comprises:
a loading chamber connected to the vacuum chamber through a loading connection;
a loading arrangement arranged to move two or more substrate racks between the loading chamber and the reaction chamber inside the vacuum chamber through the loading connection, each of the two or more substrate racks being arranged to support two or more substrates;
the reaction chamber comprising;
a support part forming a support for the two or more substrate racks; and
a cover part forming a housing surrounding the two or more substrate racks arranged on the support part,
which the support part and the cover part together form the reaction chamber such that the cover part is movably arranged with respect to the support part between an open position of the reaction chamber and a closed position of the reaction chamber,
whereby in the open position of the reaction chamber the support part and the cover part are spaced apart from each other and in the closed position of the reaction chamber the support part and the cover part are connected together for forming a closed reaction chamber;
the loading arrangement being arranged to move the two or more substrate racks together with a loading movement between the loading chamber and the reaction chamber inside the vacuum chamber through the loading connection in the open position of the reaction chamber.

34. The atomic layer deposition apparatus according to claim 33, wherein:
the two or more substrate racks are arranged in a row assembly, and that the loading arrangement is arranged to move the two or more substrate racks together in the row assembly with the loading movement between the loading chamber and the reaction chamber inside the vacuum chamber through the loading connection in the open position of the reaction chamber; or
the two or more substrate racks are arranged in contact or interconnected with each other in a row assembly such that a flow path through the two or more substrate racks is formed, and that the loading arrangement is arranged to move the two or more substrate racks together in the row assembly with the loading movement between the loading chamber and the reaction chamber inside the vacuum chamber through the loading connection in the open position of the reaction chamber.

35. The atomic layer deposition apparatus according to claim 33, wherein:
the two or more substrate racks are supported on a common rack support in the row assembly; and
the loading arrangement is arranged to move the common rack support with the loading movement between the loading chamber and the reaction chamber inside the vacuum chamber through the loading connection in the open position of the reaction chamber.

36. The atomic layer deposition apparatus according to claim 33, wherein the cover part is arranged movable in a first direction and the loading arrangement is arranged to move the two or more substrate racks in a second direction, which the second direction is transverse to the first direction.

37. The atomic layer deposition apparatus according to claim 33, the reaction chamber having a reaction space inside the reaction chamber and arranged to process multiple substrates concurrently in a batch process in the reaction space of the reaction chamber, the reaction chamber comprising:
a gas inlet arranged to supply gases into the reaction space of the reaction chamber;
a gas outlet arranged to discharge gases from the reaction space of the reaction chamber, the gas outlet being arranged spaced apart from the gas inlet; and
two or more substrate racks, each of the substrate racks being arranged to support two or more separate substrates such that a substrate batch is formed,
the two or more substrate racks are arranged inside the reaction space of the reaction chamber between the gas inlet and the gas outlet, and
the two or more substrate racks are arranged in a row assembly between the gas inlet and the gas outlet.

38. A method for loading substrates into a reaction chamber of an atomic layer deposition apparatus for processing the substrates according to the principles of atomic layer deposition method, wherein the method comprises the steps of:
arranging two or more substrate racks into a loading chamber, each of the two or more substrate racks comprise two or more substrates;
opening a loading connection between the loading chamber and a vacuum chamber;
moving the two or more substrate racks together from the loading chamber to the reaction chamber inside the vacuum chamber, the reaction chamber being in an open position in which a support part of the reaction chamber is spaced apart from a cover part of the reaction chamber; and
moving the reaction chamber from the open position to a closed position by providing a movement of the cover part with respect to the support part, in which closed position of the reaction chamber the support part and the cover part are connected together for forming a closed reaction space inside the reaction chamber.

39. The method for loading a substrate batch into a reaction chamber according to claim 38, wherein the step of moving the reaction chamber from the open position to the closed position further comprises:
moving the cover part in vertical direction with a lifter connected to the cover part; and
connecting the cover part to the support part for closing the reaction chamber.

40. The method for loading a substrate batch into a reaction chamber according to claim 38, wherein:
the step of arranging the two or more substrate racks into a loading chamber comprises:
arranging the two or more in contact or interconnected with each other in a row assembly in the loading chamber such that a flow path through the two or more substrate racks is formed, or
arranging the two or more substrate racks on a common rack support in a row assembly in the loading chamber such that a flow path through the two or more substrate racks is formed; and
the step of moving the two or more substrate racks together from the loading chamber to the reaction chamber inside the vacuum chamber comprises:
moving the two or more substrate racks together in the row assembly from the loading chamber to the reaction chamber inside the vacuum chamber, or
moving the common rack support from the loading chamber to the reaction chamber inside the vacuum chamber, the two or more substrate racks being supported on the common rack support in the row assembly.

41. The method for loading substrates into a reaction chamber of an atomic layer deposition apparatus for processing the substrates according to the principles of atomic layer deposition, wherein the method comprises the steps of:
arranging two or more substrate racks into a loading chamber, each of the two or more substrate racks comprise two or more substrates;
opening a loading connection between the loading chamber and a vacuum chamber;
moving the two or more substrate racks together from the loading chamber to the reaction chamber inside the vacuum chamber, the reaction chamber being in an open position in which a support part of the reaction chamber is spaced apart from a cover part of the reaction chamber; and
moving the reaction chamber from the open position to a closed position by providing a movement of the cover part with respect to the support part, in which closed position of the reaction chamber the support part and the cover part are connected together for forming a closed reaction space inside the reaction chamber, wherein:
the method is carried out by an atomic layer deposition apparatus arranged to process multiple substrates concurrently in a batch process, the atomic layer deposition apparatus having a reaction chamber arranged inside a vacuum chamber, wherein the atomic layer deposition apparatus further comprises:
a loading chamber connected to the vacuum chamber through a loading connection;
a loading arrangement arranged to move two or more substrate racks between the loading chamber and the reaction chamber inside the vacuum chamber through the loading connection, each of the two or more substrate racks being arranged to support two or more substrates;
the reaction chamber comprising;
a support part forming a support for the two or more substrate racks; and
a cover part forming a housing surrounding the two or more substrate racks arranged on the support part,
which the support part and the cover part together form the reaction chamber such that the cover part is movably arranged with respect to the support part between an open position of the reaction chamber and a closed position of the reaction chamber,
whereby in the open position of the reaction chamber the support part and the cover part are spaced apart from each other and in the closed position of the reaction chamber the support part and the cover part are connected together for forming a closed reaction chamber;
the loading arrangement being arranged to move the two or more substrate racks together with a loading movement between the loading chamber and the reaction chamber inside the vacuum chamber through the loading connection in the open position of the reaction chamber; or
the method is carried out by an atomic layer deposition apparatus arranged to process multiple substrates concurrently in a batch process, the atomic layer deposition apparatus having a reaction chamber arranged inside a vacuum chamber, wherein the atomic layer deposition apparatus further comprises:
a loading chamber connected to the vacuum chamber through a loading connection;
a loading arrangement arranged to move two or more substrate racks between the loading chamber and the reaction chamber inside the vacuum chamber through the loading connection, each of the two or more substrate racks being arranged to support two or more substrates;
the reaction chamber comprising;
a support part forming a support for the two or more substrate racks; and
a cover part forming a housing surrounding the two or more substrate racks arranged on the support part,
which the support part and the cover part together form the reaction chamber such that the cover part is movably arranged with respect to the support part between an open position of the reaction chamber and a closed position of the reaction chamber,
whereby in the open position of the reaction chamber the support part and the cover part are spaced apart from each other and in the closed position of the reaction chamber the support part and the cover part are connected together for forming a closed reaction chamber;
the loading arrangement being arranged to move the two or more substrate racks together with a loading movement between the loading chamber and the reaction chamber inside the vacuum chamber through the loading connection in the open position of the reaction chamber. and with a reaction chamber according to claim 22.
